(19) United States
(12) Patent Application Publication
(10) Pub. No.: US 2004/0108942 A1
(43) Pub. Date: Jun. 10, 2004

(54) Method for providing analog input device with combination key function

(76) Inventors: Wen-Kuan Lin, Taipei (TW); Chien-Chih Chen, Taipei Hsien (TW)

Correspondence Address: BIRCH STEWART KOLASCH & BIRCH, PO BOX 747, FALLS CHURCH, VA, 22040-0747, US

(21) Appl. No.: 10/315,133

(22) Filed: Dec. 10, 2002

(51) Int. Cl. H03M 11/00; H03M 1/00

(52) U.S. Cl. 341/22

(57) ABSTRACT

A method provides an analog input device with combination key function. The analog input device has more than one analog-to-digital converters and a microprocessor control unit. The microprocessor control unit identifies a position data corresponding to an output of each of the analog-to-digital converter and a corresponding key code is sent to a computer. Therefore, the analog input device has combination key function like conventional keyboards.

### FIELD OF THE INVENTION

The present invention relates to a method for providing analog input device with combination key function, especially to a method for providing analog input device with combination key function like conventional keyboards.

### BACKGROUND OF THE INVENTION

The analog input device such as capacitor-type touch pad, resistance-type touch pad, or touch screen can be used as input means as keyboard. However, one drawback for the analog input device is lack of ability for combination key input function or N key roll over function.

### SUMMARY OF THE INVENTION

It is the object of the present invention to provide a method for providing analog input device with combination key function like conventional keyboards.

In one aspect of the present invention, more than one analog-to-digital converters and a microprocessor control unit are provided. A position data corresponding to the output of each of the analog-to-digital converter can be identified by the microprocessor control unit and a corresponding key code is sent to a computer.

In another aspect of the present invention, the function of a conventional analog input device is augmented to include input function of ordinary key and combination key by arranging ordinary key and combination key in different region on the analog input device and generating different key code corresponding to the different regions.

In still another aspect of the present invention, an analog input device with N key roll over function is provided.

The various objects and advantages of the present invention will be more readily understood from the following detailed description when read in conjunction with the appended drawing, in which:

### BRIEF DESCRIPTION OF DRAWING

FIG. 1 shows a block diagram of the present invention; and

FIG. 2 shows a flowchart of the present invention.

### DETAILED DESCRIPTION OF THE INVENTION

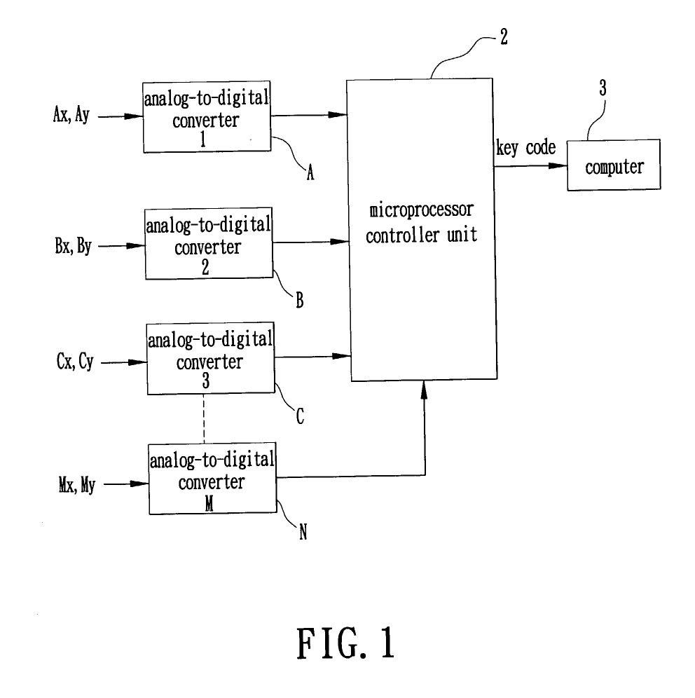

FIG. 1 shows a block diagram of the present invention, wherein an analog input device with combination key input function is disclosed. The analog input device with combination key input function, for example, can be capacitor-type touch pad, resistance-type touch pad, touch screen, or fabric keyboard, which comprises a plurality of touch keys. The components shown in FIG. 1 includes more than one analog-to-digital converters (ADC) A, B, C . . . N, a microprocessor control unit (MCU) 2, and a computer 3.

The analog-to-digital converter A ( B, C . . . N) is functioned to convert an analog signal Ax, Ay (Bx, By; Cx, Cy . . . Nx, Ny) of a touch key into a digital signal. The touch key includes combination keys and single key.

The microprocessor control unit 2 is connected to output of each of the analog-to-digital converter A, B, C . . . N. The microprocessor control unit 2 has a built-in program to identify a position data corresponding to the output of each of the analog-to-digital converter A, B, C . . . N. Therefore, the microprocessor control unit 2 can recognize a specific key code corresponding to the position data related to the output of each of the analog-to-digital converter A, B, C . . . N. Afterward, the microprocessor control unit 2 sends the key code to the computer 3.

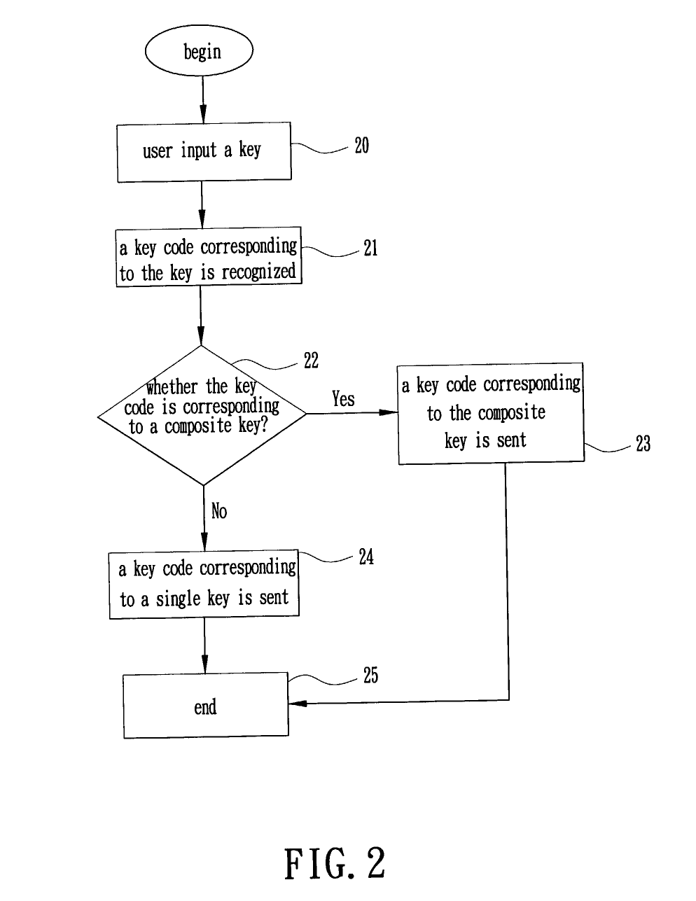

FIG. 2 shows a flowchart of the present invention. At step 20, a user presses a key on the analog input device. At step 21, a key code corresponding to the key is recognized and then step 22 judges whether the key code is corresponding to a combination key?

If true, a key code corresponding to the combination key is sent in step 23, and then finishing the task at step 25. If false, a key code corresponding to a single key is sent in step 24, and then finishing the task at step 25. Therefore, the analog input device has the ability for combination key function.

Moreover, the analog input device according to the present invention can be such adapted that the analog input device has N key roll over function.

To sum up, the analog input device according to the present invention has following advantages:

1. The analog input device has a microprocessor control unit to identify a position data corresponding to the output of different analog-to-digital converter. Therefore, a specific key code corresponding to the position data related to the output of each of the analog-to-digital converter can be sent.

2. The analog input device has both combination key function and N key roll over function.

Although the present invention has been described with reference to the preferred embodiment thereof, it will be understood that the invention is not limited to the details thereof. Various substitutions and modifications have suggested in the foregoing description, and other will occur to those of ordinary skill in the art. Therefore, all such substitutions and modifications are intended to be embraced within the scope of the invention as defined in the appended claims.

I claim:

1. A method for providing an analog input device with combination key function, comprising following steps:
(a) detecting a key on the analog input device pressed by a user;
(b) judging whether the key being pressed is a combination key?
(c) if true, sending a key code corresponding to the combination key, else sending a key code corresponding to a single key.

2. The method for providing an analog input device with combination key function as in claim 1, wherein the key is detected by more than one analog-to-digital converters in the step (a).

3. The method for providing an analog input device with combination key function as in claim 1, wherein the key being pressed is judged by a microprocessor control unit in the step (b).

4. The method for providing an analog input device with combination key function as in claim 1, wherein the key code is sent to a computer in the step (c).

5. The method for providing an analog input device with combination key function as in claim 1, wherein the analog input device is one of a capacitor-type touch pad, a resistance-type touch pad, and a fabric keyboard
